(19) United States
(12) Patent Application Publication
(10) Pub. No.: US 2016/0042916 A1
(43) Pub. Date: Feb. 11, 2016

(54) POST-CHAMBER ABATEMENT USING UPSTREAM PLASMA SOURCES

(71) Applicant: Applied Materials, Inc., Santa Clara, CA (US)

(72) Inventor: Rongping WANG, Cupertino, CA (US)

(21) Appl. No.: 14/737,073

(22) Filed: Jun. 11, 2015

Related U.S. Application Data
(60) Provisional application No. 62/033,774, filed on Aug. 6, 2014.

(51) Int. Cl. H01J 37/32; C23C 16/511; C23C 16/44; B08B 7/00; C23C 16/50

(52) U.S. Cl. CPC H01J 37/321; B08B 7/0035; C23C 16/50; C23C 16/4412; C23C 16/511; H01J 37/3244

(57) ABSTRACT

Embodiments of the disclosure relate to a remote plasma source for cleaning an exhaust pipe. In one embodiment, an apparatus includes a substrate processing chamber, a pump positioned to evacuate the substrate processing chamber, and an abatement system. The abatement system comprises a plasma gas delivery system positioned between the substrate processing chamber and the pump, the gas delivery system having a first end coupling to the substrate processing chamber and a second end coupling to the pump, a reactor body connected to the gas delivery system through a delivery member, a cleaning gas source connected to the reactor body, and a power source positioned to ionize within the reactor body a cleaning gas from the cleaning gas source. Radicals and species of the cleaning gas react with post-process gases from the substrate processing chamber to convert them into a environmentally and process equipment friendly composition before entering the pump.

### CROSS-REFERENCE TO RELATED APPLICATIONS

This application claims benefit of U.S. provisional patent application Ser. No. 62/033,774, filed Aug. 6, 2014, which is herein incorporated by reference.

### BACKGROUND

1. Field

Embodiments of the present disclosure generally relate to an abatement system using a plasma source to reduce deposition species inside an exhaust system for a chamber, with minimum impact to process parameters, e.g. chamber pressure.

2. Description of the Related Art

Semiconductor manufacturing processes utilize a variety of chemicals, many of which have extremely low human tolerance levels. During processing (e.g. physical vapor deposition, diffusion, etch processes, epitaxial deposition, etc.), some of the tools used (e.g., chemical vapor deposition chamber, dielectric or conductor plasma etch chamber, diffusion, etc.) as well as the processes may produce undesirable byproducts including, for example, perfluorcompounds (PFCs) or byproducts that may decompose to form PFCs. PFCs are recognized to be strong contributors to global warming.

These undesirable byproducts are exhausted from semiconductor manufacturing tools by an exhaust pump to an abatement system. The abatement system converts these undesirable byproducts produced by the processing of substrates to less environmentally harmful versions to be emitted to the atmosphere. However, for many processes the exhaust pipeline and pump may be exposed to high contents of deposition species. These deposition species and their condensation inside the exhaust pumps build up a thin layer of dielectric film on the pump components such as pump blades, leading to a loss of pumping performance and ultimately pump failure.

Therefore, there is a need in the art for an improved abatement system that effectively reduces the condensation of deposition species within the exhaust pump and improves pumping performance.

### SUMMARY

Embodiments of the disclosure relate to a post-chamber abatement system using a remote plasma source to reduce deposition species inside an exhaust system, with minimum impact to process parameters such as chamber pressure. The onset time for the post-chamber abatement system is flexible, which can be ongoing with the process (either full or partial time), or can be designated to avoid certain sensitive process steps and be on during clean or wafer transfer stages. In one embodiment, an apparatus includes a substrate processing chamber having a substrate support disposed therein, a pump positioned to evacuate the substrate processing chamber, an abatement system. The abatement system includes a plasma gas delivery system positioned between the substrate processing chamber and the pump, the gas delivery system having a first end coupling to the substrate processing chamber and a second end coupling to the pump, a reactor body connected to the gas delivery system through a delivery member, the reactor body defining a plasma excitation region therein, a cleaning gas source connected to the reactor body, and a power source positioned to ionize within the plasma excitation region a cleaning gas from the cleaning gas source.

In another embodiment, the apparatus comprises a substrate processing chamber having a substrate support disposed therein, a pump positioned to evacuate the substrate processing chamber, and an abatement system. The abatement system includes a plasma gas delivery system positioned between the substrate processing chamber and the pump, the gas delivery system having a first end coupling to the substrate processing chamber and a second end coupling to the pump, a reactor body connected to the plasma gas delivery system through a delivery member, the reactor body defining a plasma excitation region therein, wherein the delivery member is heated by a heating element, a plurality of magnets disposed approximately around the reactor body to azimuthally provide a magnet field into the plasma excitation region of the reactor body, a cleaning gas source connected to the reactor body, and a power source positioned to ionize within the plasma excitation region a cleaning gas from the cleaning gas source.

In yet another embodiment, the apparatus comprises a substrate processing chamber having a substrate support disposed therein, a vacuum pump disposed downstream of the substrate processing chamber to evacuate the substrate processing chamber, and an abatement system positioned in a flow path between the substrate processing chamber and the vacuum pump. The abatement system includes a reactor body between defining a plasma excitation region therein, an abatement gas delivery system connected to a first end of the reactor body through a gas line, a plasma gas delivery system connected to a second end of the reactor body through a delivery member, wherein a first end of the plasma gas delivery system is connected to the substrate processing chamber, and a second end of the plasma gas delivery system is connected to the pump, and an ion filter disposed between the reactor body and the plasma gas delivery system to allow only radicals and/or energetically excited neutral species of the abatement reagent into the plasma gas delivery system through the delivery member.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a schematic, conceptual diagram of an abatement system having a remote plasma source according to embodiments of the present disclosure.

FIG. 2 is a schematic, conceptual diagram of an abatement system having a remote plasma source according to embodiments of the present disclosure.

FIG. 3 is a schematic, conceptual diagram of an abatement system having a remote plasma source according to embodiments of the present disclosure.

FIG. 4A depicts a schematic top view of a reactor body that may be used in place of the reactor body of FIGS. 1-3 according to embodiments of the present disclosure.

FIG. 4B depicts a schematic cross-sectional view of the reactor body of FIG. 4A having a gas distribution plate disposed thereon according to embodiments of the disclosure.

FIG. 5A depicts a schematic top view of a reactor body that may be used in place of the reactor body of FIGS. 1-3 according to embodiments of the present disclosure.

FIG. 5B depicts a schematic cross-sectional view of the reactor body of FIG. 5A having a gas distribution plate disposed thereon according to embodiments of the disclosure.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

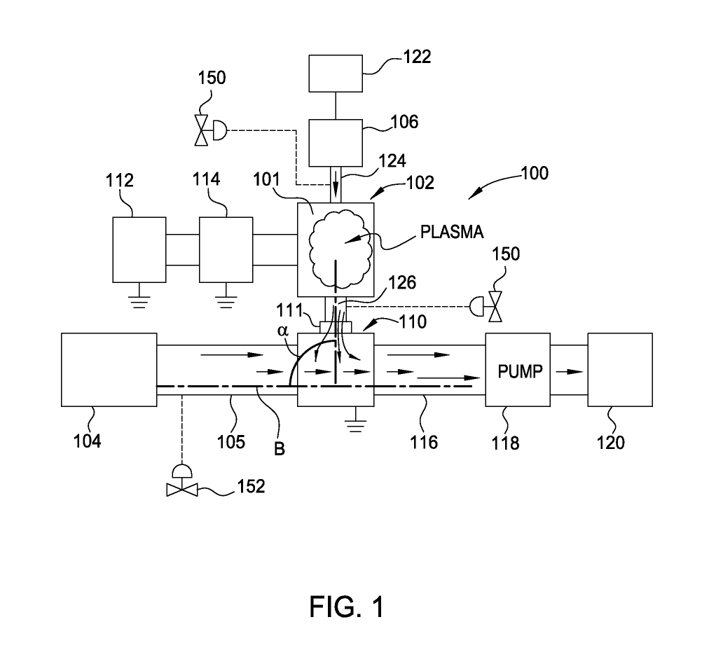

FIG. 1 is a schematic, conceptual diagram of an abatement system 100 having a remote plasma source 102 according to embodiments of the present disclosure. The abatement system 100 is generally disposed between a substrate processing chamber 104 and a pump 118. The abatement system 100 includes a remote plasma source 102 for cleaning the pump 118 and the path flow between the substrate processing chamber 104 and the pump 118. Particularly, the remote plasma source 102 generates radicals and/or energetically excited neutral species from an abatement reagent to perform an abatement process on gases and/or other materials exiting the substrate processing chamber 104 so that such gases and/or other materials may be converted into a more environmentally and/or process equipment friendly composition.

The substrate processing chamber 104 is generally configured to perform at least one integrated circuit manufacturing process, such as a deposition process, an etch process, a plasma treatment process, a pre-clean process, an ion implant process, or other integrated circuit manufacturing process. The process performed in the substrate processing chamber 104 may be thermal-assisted or plasma-assisted. In one example, the process performed in the substrate processing chamber 104 is a plasma deposition process for depositing a silicon-based material on a substrate, which is positioned on a substrate support disposed within the substrate processing chamber 104.

In general, the abatement system 100 includes a reactor body 101, which acts as the remote plasma source, an abatement gas delivery system 106, a plasma gas delivery system 110, a power source 112, and a power delivery system 114. The substrate processing chamber 104 has a chamber exhaust coupled by a pipeline 105 to the plasma gas delivery system 110, where the radicals and/or energetically excited neutral species generated from the reactor body 101 are reacted with the post-process gases exhausted from the substrate processing chamber 104. The exhaust of the plasma gas delivery system 110 is coupled by an exhaust conduit 116 to a pump 118 and facility exhaust 120. The pump 118 may be a vacuum pump utilized to evacuate the substrate processing chamber 104, while the facility exhaust 120 generally includes scrubbers or other exhaust cleaning apparatus for preparing the effluent of the substrate processing chamber 104 to enter the atmosphere.

In various embodiments, the reactor body 101 is disposed externally to the pump 118. The reactor body 101 may be positioned upstream of the plasma gas delivery system 110. The reactor body 101 is separated, in structure, from the plasma gas delivery system 110. Therefore, the reactor body 101 is physically isolated from the pipeline 105, the exhaust conduit 116 and the pump 118. In one embodiment, the plasma gas delivery system 110 is disposed in a flow path between the substrate processing chamber 104 and the pump 118. The plasma gas delivery system 110 has a first end coupling to the substrate processing chamber and a second end coupling to the pump so that the post-process gases coming out of the substrate processing chamber 104 will first encounter the plasma gas delivery system 110, followed by the pump 118. In some embodiments, the plasma gas delivery system 110 is disposed approximate to the pump 118 to minimize loss of reactive species.

The abatement gas delivery system 106 is connected to an abating agent source 122. The abatement gas delivery system 106 is adapted to deliver one or more abatement reagents, which is typically clean and non-deposition gas, from the abating agent source 122 into the reactor body 101 through a gas line 124. The abatement reagent may be activated in the reactor body 101 by exposure to an excitation energy such as RF, DC, microwave, UV, intense heat, or electron synchrotron radiation. The remote plasma source 102 may be an inductively coupled plasma (ICP) chamber, a capacitively coupled plasma (CCP) chamber, a microwave induced (μW) plasma chamber, an electron cyclotron resonance (ECR) chamber, a high density plasma (HDP) chamber, an ultraviolet (UV) chamber, the filament of a hot wire chemical vapor deposition (HW-CVD) chamber, or any chamber that is capable of generating radicals and/or energetically excited neutral species from the abatement reagent. In some embodiments, the reactor body 101 may include any two or more chambers mentioned above.

In one example, the reactor body 101 is an ICP chamber or a CCP chamber. In another example, the reactor body 101 is a hybrid chamber including an ICP configuration and a CCP configuration. In such a case, the reactor body 101 can be configured to switch between an ICP mode and a CCP mode. For example, the reactor body 101 may be an inductive coupled plasma reactor having a capacitively coupled electrode positioned therein. Depending upon the post-process gases to be processed and/or the pressure within the reactor body 101, the plasma may be first ignited by the capacitively coupled electrode and then sustained by the inductive coupled plasma reactor. The capacitively coupled electrode may be advantageous if the pressure within the reactor body 101 is above about 2 Torr, while the inductive coupled electrode may be advantageous if the pressure within the reactor body 101 is below about 2 Torr.

The abatement reagent may include any cleaning gases such as, for example, CH₄, H₂O, H₂, NF₃, SF₆, F₂, HCl, HF, Cl₂, HBr, H₂, H₂O, O₂, N₂, O₃, CO, CO₂, NH₃, N₂O, CH₄, and combinations thereof. Any other suitable fluorine-containing gas or halogen-containing gas may also be used. The abatement reagent may also include a combination of CHₓF_{y} (where x=1 to 3 and y=4-x) and O₂ and/or H₂O, and a combination of CFₓ ((where x is a number between 0 and 2) and O₂ and/or H₂O. It is contemplated that different abatement reagent may be used for effluent having different compositions.

The abatement reagent is energized/excited into a plasma within the reactor body 101 using power from the power source 112. In some embodiments, the power source 112 may be a radio frequency (RF) power source and/or a direct current (DC) power source configured to provide a continuous RF power, a continuous DC power, a RF power having a RF pulsing frequency (e.g., 0.25-10 kHz), or a DC power having a DC pulsing frequency (e.g., 5-100 kHz). The abatement reagent may be ignited within the reactor body 101 through application of equilibrium plasma discharge or non-equilibrium plasma discharge. In one embodiment, the abatement reagent is ignited through non-equilibrium plasma discharge. Non-equilibrium plasma may be formed by exposing the abatement reagent to a high frequency (e.g., 13.56 MHz) output power at a low gaseous pressure (e.g., less than 100 Torr, for example about 20 Torr or less) within the reactor body 101. The power source 112 may be configured to deliver an adjustable amount of power to the electrode of the reactor body 101 depending on the abatement reagent used. The power may be tuned by the power delivery system 114. For example, the power delivery system 114 may be a matching network used to tune the RF power if the power source 112 is a RF power source.

The reactor body 101 is connected to the plasma gas delivery system 110 through a delivery member 126. The delivery member 126 may have a minimum length needed to deliver radicals and/or energetically excited neutral species from the reactor body 101 to the plasma gas delivery system 110. In some cases, the delivery member 126 may be heated using any suitable heating source (such as a lamp or resistive heating element) to reduce recombination of the excited species on or near the surface. The delivery member 126 may be held at an angle “α” with respect to a longitudinal axis “B” of the pipeline 105 to minimize loss of reactive species. In most examples, the angle “α” is about 60° to about 110°, for example about 90°.

Various ion filters, such as electrostatic filters operated at a bias of, for example, about 200V (RF or DC), wire or mesh filters, magnetic filters, or any ion suppression elements, any of which may have a dielectric coating, may be disposed between the reactor body 101 and the plasma gas delivery system 110. In one embodiment, the ion filter is disposed within the delivery member 126. The ion filter is configured so that only radicals and/or energetically excited neutral species of the abatement reagent are introduced into the plasma gas delivery system 110. In some cases where ion filters are not used within the delivery member 126, the delivery member 126 may be positioned at an angle “α” of about 10° to about 70°, for example about 20° to about 45°, to promote collision of ions or reaction of ions with electrons or other charged particles. The use of the ion filters and/or angled delivery member 126 ensures the majority or all ions are eliminated prior to entering the plasma gas delivery system 110. The radicals and/or energetically excited neutral species of the abatement reagent are expected to react with, and convert post-process gases and/or other materials exiting the substrate processing chamber 104 into a more environmentally and/or process equipment friendly composition.

The plasma gas delivery system 110 is connected to the pipeline 105 at one end of the plasma gas delivery system 110 and to the exhaust conduit 116 at the opposing end of the plasma gas delivery system 110. The plasma gas delivery system 110 may be heated with electrical power or continuous plasma at different power levels to enhance the reaction. The plasma gas delivery system 110 may have one or more gas inlets 111 in fluid communication with the delivery member 126 to distribute radicals and/or energetically excited neutral species from the reactor body 101 into the plasma gas delivery system 110. If multiple gas inlets are adapted, the gas inlets may be arranged coplanar with each other to evenly distribute the radicals and/or energetically excited neutral species. Alternatively, the plasma gas delivery system 110 may be configured so that multiple gas inlets are evenly spaced around the circumference of the pipeline 105 passing through the plasma gas delivery system 110. In this way, the post-process gases can be uniformly and effectively reacted with radicals and/or energetically excited neutral species.

In various embodiments, a first pressure regulating device 150 may be disposed anywhere between the abatement gas delivery system 106 and the reactor body 101, and/or anywhere between the reactor body 101 and the plasma gas delivery system 110. The first pressure regulating device is configured so that the pressure in the abatement gas delivery system 106 is regulated to be relatively higher than the pressure in the remote plasma source 102, and the pressure inside the reactor body 101 is regulated to be relatively higher than the pressure in the pipeline 105. Therefore, the radicals and/or energetically excited neutral species of the abatement reagent are directed to flow downstream into the plasma gas delivery system 110 under the pressure difference. In some embodiments, a second pressure regulating device 152 may be disposed anywhere between the substrate processing chamber 104 and the plasma gas delivery system 110 so that the pressure in the pipeline 105 is regulated to be relatively higher than the pressure in the plasma gas delivery system 110. The first and second pressure regulating device may be controlled by a pressure regulator (not shown) such that the post-process gases, converted compositions and/or any undesired gases or materials are prevented from intruding into the substrate processing chamber 104 but instead are directed to flow to the exhaust conduit 116. The first and second pressure regulating devices may be any structural and operational features configured to prevent significant backflow of plasma, radicals and/or energetically excited neutral species, or processed gases from the plasma gas delivery system 110 back into the reactor body 101 and/or the substrate processing chamber 104.

The operational features may include maintaining a pressure difference between the abatement gas delivery system 106 and the reactor body 101 that maintains a unidirectional flow of plasma or gas(es) through the delivery member 126, and/or between the abatement gas delivery system 106 and the substrate processing chamber 104. The structural features may include, for example, a flow limiter such as an orifice plate that has selection of dimensions and cross-sectional geometry of the orifices that deactivates backstreaming plasma or gas(es). Any other component that is capable of controlling fluid pressure flow and/or maintaining a constant pressure drop across the pressure regulating devices may also be used.

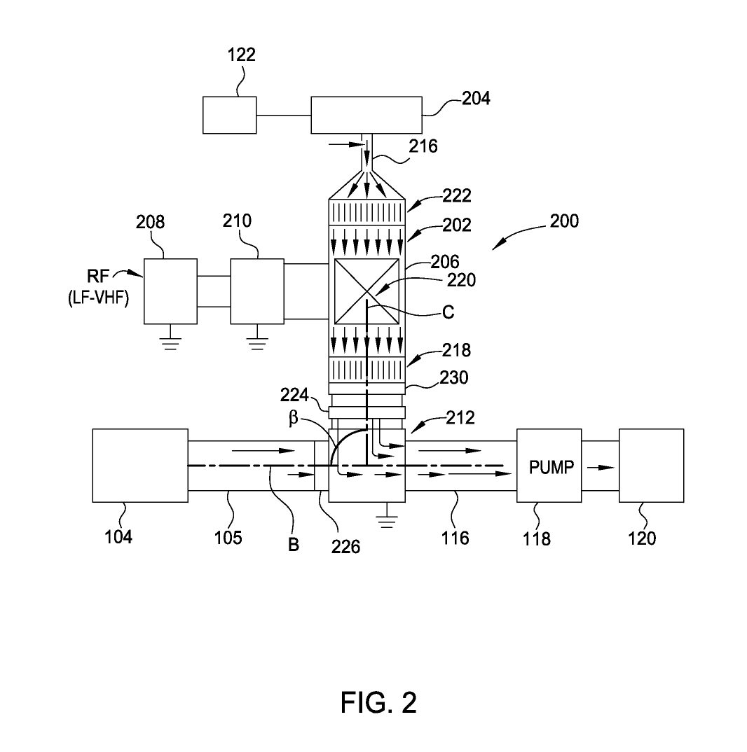

FIG. 2 is a schematic, conceptual diagram of an abatement system 200 having a remote plasma source 202 according to embodiments of the present disclosure. The abatement system 200 is conceptually similar to the abatement system 100 except that the remote plasma source 202 is an inductively coupled plasma (ICP) source. The abatement system 200 may be positioned between the substrate processing chamber 104 and the pump 118. The abatement system 200 generally includes an abatement gas delivery system 204, a reactor body 206, a radio frequency (RF) source 208, a power delivery system 210, and a plasma gas delivery system 212. Similarly, the abatement gas delivery system 204 is connected to an abating agent source 122. The substrate processing chamber 104 has a chamber exhaust coupled by a pipeline 105 to the downstream plasma gas delivery system 212, where the radicals and/or energetically excited neutral species generated from the reactor body 206 are reacted with the post-process gases exhausted from the substrate processing chamber 104. The exhaust of the plasma gas delivery system 212 is coupled by an exhaust conduit 116 to the pump 118 and facility exhaust 120.

The abatement gas delivery system 204 is adapted to deliver one or more abatement reagents, which is typically clean and non-deposition gas, from the abating agent source 122 into the reactor body 206 through a gas line 216. A pressure regulating device 222 may be provided between the gas line 216 and the reactor body 206 to create a pressure difference between the abatement gas delivery system 204 and the reactor body 206, as will be discussed below. The reactor body 206 may have a cylindrical or any shape defining a plasma excitation region therein. The reactor body 206 may be made of, or have a dielectric coating (e.g., quartz, ceramic material (e.g., alumina)) disposed on the interior surface of the reactor body 206. The reactor body 206 may be evacuated so that the plasma excitation region is maintained at a vacuum pressure during the process.

The RF source 208 and the power delivery system 210 may be connected to a coil or antenna 220, or an electrode disposed within the reactor body 206. The coil or antenna 220 may be shaped and positioned with respect to the reactor body 206 to inductively couple RF energy delivered from the RF source 208 into the reactor body 206 and thus create and sustain the plasma in the plasma excitation region. Other excitation energy, such as an energy having a microwave frequency, may also be used to excite the abatement gases in the reactor body 206. The coil or antenna 220 may be positioned within, on, or adjacent to the reactor body 206. For example, the coil or antenna 220 may be positioned around or proximate the top portion and/or another end of the reactor body 206 to create a plasma within the reactor body 206. The coil or antenna 220 may be positioned on one side of a dielectric plate or window (made of quartz, for example) in the wall of the reactor body 206. Electromagnetic energy from the coil or antenna 220 is coupled through the dielectric plate or window and into the plasma.

In some embodiments, the coil or antenna 220 may be a planar antenna having a helical or spiral pattern to enhance plasma density and uniformity within the reactor body 206. The planar antenna may be positioned at any location proximate the reactor body 206. For example, the planar antenna may be positioned on the sides or top or lower end of the reactor body 206 to inductively couple the power into the plasma. In some embodiments, one end of the coil or antenna 220 may be electrically grounded, while the other end of the coil or antenna 220 is connected to the RF source 208. In some embodiments, the pressure regulating device coupling to the reactor body 206 may be electrically grounded.

In some embodiments, the coil or antenna 220 may be electrically isolated from the RF source 208 so that the potential of the coil or antenna 220 floats. In such a case, an isolation transformer (not shown) may be further provided. The isolation transformer may have its primary winding connected across the output of the RF source 208 and its secondary winding connected across the coil or antenna 220. The primary and secondary windings may be wire conductors wound around a cylindrical core (not shown). In any case, the RF source 208 provides RF energy to the coil or antenna 220, and the abatement reagent within the reactor body 206 is ionized to become a plasma energized by RF energy inductively coupled from the coil or antenna 220.

The RF source 208 may operate at between about 0 and about 10 kW at a frequency between about 10 kHz and about 60 MHz. The RF source 208 may be a low frequency power source, a very high frequency (VHF) power source, or a combination of both. The low frequency power source may deliver adjustable RF power at a frequency at or below about 20 MHz while the VHF power source may deliver adjustable VHF power at a frequency at or above 30 MHz. VHF may be advantageous in certain processes since it can maintain high-density plasma under a low self-bias voltage. The power delivery system 210 may include a cable and a matching network, or a resonant interface circuit used to tune the RF power delivered by the RF source 208. If a low frequency power source is used, the power delivery system 210 may be a low frequency matching network. If a high frequency power source is used, the power delivery system 210 may be a high frequency matching network. The RF source 208 may be operated in continuous wave mode, always on, or can be operated in pulsed mode, where the source power is on and off at a frequency of 100 Hz to 100 kHz.

The reactor body 206 is connected to the plasma gas delivery system 212 through a delivery member 218. An ion filter 230 as discussed above with respect to FIG. 1 may be disposed between the reactor body 206 and the plasma gas delivery system 212, for example in the delivery member 218, so that only radicals and/or energetically excited neutral species of the abatement reagent are introduced into the downstream plasma gas delivery system 212. Similarly, the delivery member 218 may have a minimum length needed to deliver radicals and/or energetically excited neutral species from the reactor body 206 to the downstream plasma gas delivery system 212. The central axis “C” of the delivery member 218 is made short to minimize loss of reactive species. In some cases, the delivery member 218 can be heated using any suitable heating source (such as a lamp or resistive heating element) to minimize recombination of reactive species on or near the surface. The delivery member 218 may be held at an angle “β” with respect to a longitudinal axis “B” of the pipeline 105. In most examples, the angle “β” is about 60° to about 110°, for example about 90. In cases where ion filters are not used within the delivery member 218, the delivery member 218 may be held at an angle “β” of about 10° to about 70°, for example about 20° to about 45°, to promote collision of ions or reaction of ions with electrons or other charged particles. The use of the ion filter and/or the angled delivery member 218 ensure the majority or all ions are eliminated prior to entering the downstream plasma gas delivery system 212. In any case, the radicals and/or energetically excited neutral species of the abatement reagent are expected to react with, and convert post-process gases and/or other materials exiting the substrate processing chamber 104 into a more environmentally and/or process equipment friendly composition.

In various embodiments, a first pressure regulating device 222, 224 may be disposed between the abatement gas delivery system 204 and the reactor body 206, and/or between the reactor body 206 and the plasma gas delivery system 212. The first pressure regulating devices 222, 224 are configured so that the pressure inside the abatement gas delivery system 204 is relatively higher than the pressure inside the reactor body 206, and the pressure inside the reactor body 206 is relatively higher than the pressure inside the pipeline 105. Therefore, the radicals and/or energetically excited neutral species of the abatement reagent are directed to flow downstream into the plasma gas delivery system 212 under the pressure difference. A second pressure regulating device 226 may be optionally disposed between the substrate processing chamber 104 and the plasma gas delivery system 212 so that the post-process gases, converted compositions and/or any undesired gases or materials are directed to flow to the exhaust conduit 116. The first and second pressure regulating devices may be those structural and operational features discussed above with respect to FIG. 1, which are configured to prevent significant backflow of plasma, radicals and/or energetically excited neutral species, or processed gases from the plasma gas delivery system 212 back into the reactor body 206 and/or the substrate processing chamber 104.

In operation, the abatement reagents, which are clean and non-deposition gases, are introduced into the reactor body 206 through the gas line 216. The coil or antenna 220 positioned proximate the reactor body 206 is powered by the RF source 208 to inductively couple energy into the reactor body 206 and generate high density plasma from the abatement reagents within the reactor body 206. The generated plasma is filtered by an ion filter 230 so that the majority or all ions are eliminated prior to entering the downstream plasma gas delivery system 212. The radicals and/or energetically excited neutral species of the abatement reagent then react with post-process gases and/or other materials exiting the substrate processing chamber 104 to convert them into a more environmentally and/or process equipment friendly composition before entering the pump 118. As a result, the condensation of deposition species within the pump 118 is avoided or minimized.

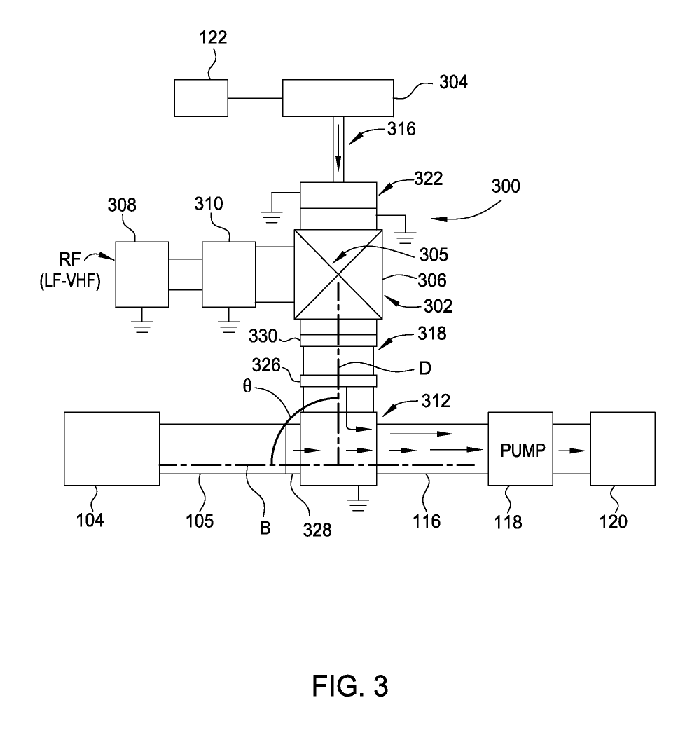

FIG. 3 is a schematic, conceptual diagram of an abatement system 300 having a remote plasma source 302 according to embodiments of the present disclosure. The abatement system 300 is conceptually similar to the abatement system 100 except that the remote plasma source 302 is a capacitively coupled plasma (CCP) source. The abatement system 300 may be positioned between the substrate processing chamber 104 and the pump 118. The abatement system 300 generally includes an abatement gas delivery system 304, a reactor body 306, a power source 308, a power delivery system 310, and a plasma gas delivery system 312. The abatement gas delivery system 304 is connected to an abating agent source 122. The substrate processing chamber 104 has a chamber exhaust coupled by a pipeline 105 to the downstream plasma gas delivery system 312, where the radicals and/or energetically excited neutral species generated from the reactor body 306 are reacted with the post-process gases exhausted from the substrate processing chamber 104. The exhaust of the plasma gas delivery system 312 is coupled by an exhaust conduit 116 to the pump 118 and facility exhaust 120.

The abatement gas delivery system 304 is adapted to deliver one or more abatement reagents, which is typically clean and non-deposition gas, from the abating agent source 122 into the reactor body 306 through a gas line 316. A pressure regulating device 322 is provided between the gas line 316 and the reactor body 306 to create a pressure difference between the abatement gas delivery system 304 and the reactor body 306. The pressure regulating device 322 is configured so that the radicals and/or energetically excited neutral species of the abatement reagent are directed to flow downstream into the plasma gas delivery system 312 under the pressure difference. In some embodiments, the pressure regulating device 322 may serve as an electrode (e.g., anode). For example, the pressure regulating device 322 may be grounded or electrically isolated from the RF source 308 so that the potential of the pressure regulating device 322 floats.

An additional pressure regulating device 326 may be disposed between the reactor body 306 and the plasma gas delivery system 312. The pressure regulating devices 322, 326 are configured so that the pressure inside the reactor body 306 is relatively higher than the pressure inside the pipeline 105. Therefore, the radicals and/or energetically excited neutral species of the abatement reagent are directed to flow downstream into the plasma gas delivery system 312 under the pressure difference. Optionally, a pressure regulating device 328 may be disposed between the substrate processing chamber 104 and the plasma gas delivery system 312 so that the post-process gases, converted compositions and/or any undesired gases or materials are directed to flow to the exhaust conduit 116. The pressure regulating devices described herein may be those structural and operational features discussed above with respect to FIG. 1, which are configured to prevent significant backflow of plasma, radicals and/or energetically excited neutral species, or processed gases from the plasma gas delivery system 312 back into the reactor body 306 and/or the substrate processing chamber 104.

The reactor body 306 may have a cylindrical or any shape defining a plasma excitation region therein. The reactor body 306 is evacuated so that the plasma excitation region is maintained at a vacuum pressure during the process. The reactor body 306 may be made of metal material such as aluminum or stainless steel, or coated metal, such as anodized aluminum or aluminum coated with nickel. Alternatively, the reactor body 306 may be made of insulating material, such as quartz or ceramic.

The power source 308 and the power delivery system 310 may be connected to an electrode of the reactor body 306. Any components disposed within the reactor body 306, such as the pressure regulating device 322 and/or the plasma gas delivery system 312, may be grounded and serve as an anode. In some embodiments, the power source 308 and the power delivery system 310 may be connected to an electrode (i.e., cathode) that is disposed within the reactor body 306. In some embodiments, the reactor body 306 may be grounded and the power source 308 and the power delivery system 310 are connected to an electrode (i.e., cathode) that is disposed within the reactor body 306. In some embodiments, the reactor body 306 may comprise of a first and a second chamber body pieces, with a dielectric isolator disposed between the first and second chamber body pieces. In such a case, the first chamber body piece may be powered by the power source 308 while the second chamber body piece may be connected to the ground.

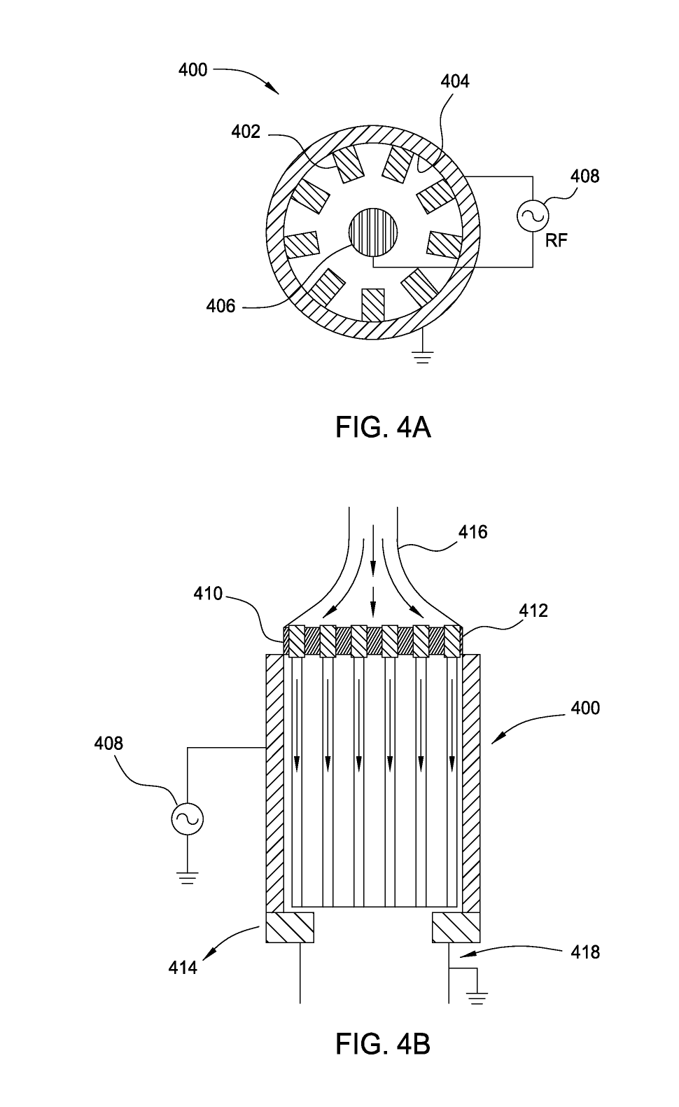

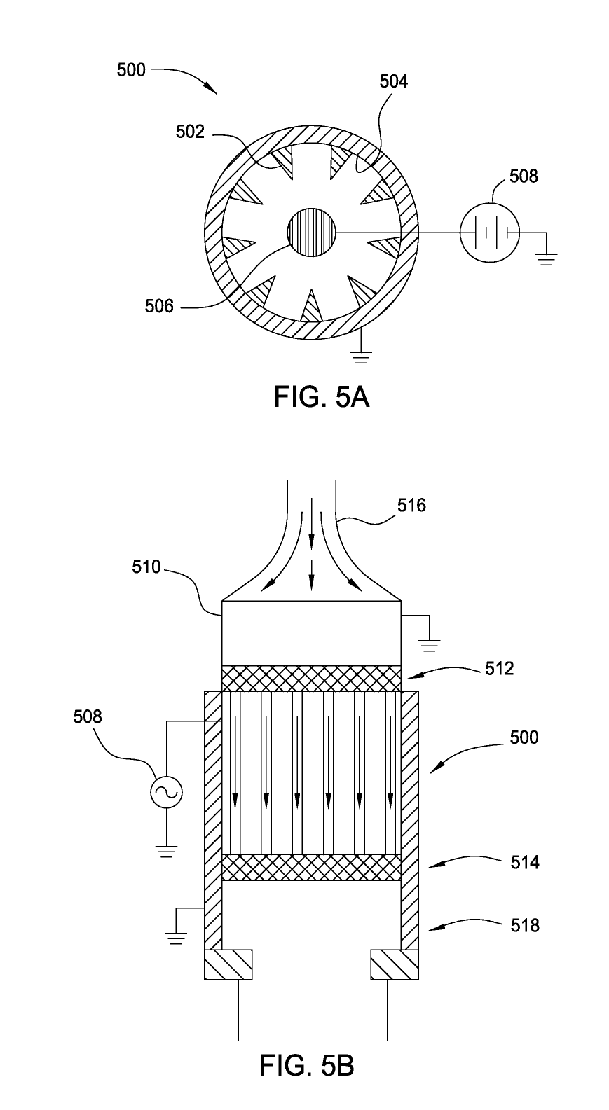

In some embodiments, the reactor body 306 may be a hollow cathode 305. The hollow cathode 305 may be isolated from the anodes by an isolator. The hollow cathode 305 may be powered by the power source 308. In some embodiments, a gas distribution plate may be further provided between the gas line 316 and the reactor body 306 to allow evenly distribution of the abatement reagents into the reactor body 306. The gas distribution plate may be disposed on top of the reactor body 306 or within the reactor body 306. In some embodiments, the gas distribution plate may be powered by the power source 308. In some embodiments, the gas distribution plate may be grounded. In some embodiments, the gas distribution plate may be electrically isolated from the reactor body 306. Various configurations of the reactor body 306 and the gas distribution plate are further discussed below with respect to FIGS. 4A, 4B and 5A, 5B.

The power source 308 may be a radio frequency (RF) power source and/or a direct current (DC) power source configured to provide a continuous RF power, a continuous DC power, a RF power having a RF pulsing frequency (e.g., 0.25-10 kHz), or a DC power having a DC pulsing frequency (e.g., 5-100 kHz). If RF power is used, the power source 308 may be a low frequency power source, a very high frequency (VHF) power source, or a combination of both. The low frequency power source may deliver adjustable RF power at a frequency at or below about 20 MHz while the VHF power source may deliver adjustable VHF power at a frequency at or above 30 MHz. The power source 308 may be configured to deliver an adjustable amount of power to the reactor body 306 depending on the abatement reagent used. The power delivery system 310 may include a cable and a matching network, or a resonant interface circuit used to tune the power delivered by the power source 308.

The reactor body 306 is connected to the plasma gas delivery system 312 through a delivery member 318. An ion filter 330 as discussed above with respect to FIG. 1 may be disposed between the reactor body 306 and the plasma gas delivery system 312, for example in the delivery member 318. In this way, only radicals and/or energetically excited neutral species of the abatement reagent are introduced into the downstream plasma gas delivery system 312. The delivery member 318 may have a minimum length needed to deliver radicals and/or energetically excited neutral species from the reactor body 306 to the downstream plasma gas delivery system 312. Similarly, the delivery member 318 is made short and can be heated to minimize loss of reactive species, as discussed above with respect to the delivery member 218. The central axis “D” of the delivery member 318 may be held at an angle “θ” with respect to a longitudinal axis “B” of the pipeline 105. In most examples, the angle “θ” is about 60° to about 110°, for example about 90. In cases where ion filters are not used within the delivery member 318, the delivery member 318 may be held at an angle “θ” of about 10° to about 70°, for example about 20° to about 45°, to promote collision of ions or reaction of ions with electrons or other charged particles. The use of the ion filter and/or the angled delivery member 318 ensure the majority or all ions are eliminated prior to entering the downstream plasma gas delivery system 312. In any case, the radicals and/or energetically excited neutral species of the abatement reagent are expected to react with, and convert post-process gases and/or other materials exiting the substrate processing chamber 104 into a more environmentally and/or process equipment friendly composition.

In operation, the abatement reagents, which are clean and non-deposition gases, are introduced into the reactor body 306 through the gas line 316. The cathode of the reactor body 306 is powered by the power source 308 to generate plasma (from the abatement reagents) between the cathode and the anode, which could be the pressure regulating device 322, a part of the reactor body 306, or the plasma gas delivery system 312. The generated plasma is filtered by an ion filter 330 so that the majority or all ions are eliminated prior to entering the downstream plasma gas delivery system 312. The radicals and/or energetically excited neutral species of the abatement reagent then react with post-process gases and/or other materials exiting the substrate processing chamber 104 to convert them into a more environmentally and/or process equipment friendly composition before entering the pump 118. As a result, the condensation of deposition species within the pump 118 is avoided or minimized.

FIG. 4A depicts a schematic top view of a reactor body 400 that may be used in place of the reactor body of FIGS. 1-3 according to embodiments of the present disclosure. The reactor body 400 may have a cylindrical shape defining a plasma excitation region therein. The reactor body 400 may be made of metal material, for example aluminum or stainless steel. Alternatively, the reactor body 400 may be made of coated metal, for example anodized aluminum or aluminum coated with nickel. Alternatively, the reactor body 400 may be made of refractory metal. Alternatively, the reactor body 400 may be made of insulating material, such as quartz or ceramic, or may be made of any other material that is suitable for performing a plasma process.

The reactor body 400 may have a plurality of extrusions 402 extended inwardly from an interior surface of the reactor body 400 to a central electrode 406 disposed within the reactor body 400. The extrusions 402 are electrically conductive and can enhance gas ionization and boost plasma density. The extrusions 402 may be machined out of a metal cylinder (i.e., the reactor body 400). Each of the extrusions 402 may serve as an electrode. The extrusions 402 may be evenly spaced around the inner circumference 404 of the reactor body 400. Any two or more closely spaced extrusions, especially two neighboring extrusions, form an effective hollow cathode region between their surfaces. Plasma formed in that region is characterized by a sheath at both electrode surfaces. Electrons which are emitted from the electrode surface (due to ion bombardment) are accelerated into the plasma across the sheath and repelled by the sheaths at both electrode surfaces, and thus are not able to escape from the discharge region. These entrapped electrons cause a high level of ionization of the gas and thus very dense plasma between the electrodes. Particularly, the formed plasma has a low impedance (low voltage on the electrodes), allowing a high effective current flow at relatively modest power levels.

A power source 408, such as those power sources mentioned in FIGS. 1-3, may have one end connected to extrusions 402 formed within the reactor body 400 to provide power to the extrusions 402, and another end connected to the central electrode 406. In some embodiments, the reactor body 400 may be connected to the ground. The power source 408 may be a radio frequency (RF) power source and/or a direct current (DC) power source configured to provide a continuous RF power, a continuous DC power, a RF power having a RF pulsing frequency (e.g., 0.25-10 kHz), or a DC power having a DC pulsing frequency (e.g., 5-100 kHz).

In one embodiment, the reactor body 400 may be an ionization enhanced reactor using an externally applied magnetic field. The magnetic field can be applied through an array of permanent magnets, e.g. rare-earth magnets, or a Helmholtz coil, disposed approximately the reactor body 400. The magnetic field is applied to confine the charged particles and keep them inside the reaction volume, thereby enhancing plasma density inside the reactor body. The arrangement of the magnets may be equally spaced around the reactor body 400. Magnetic field can be applied vertically or horizontally with respect to any reference component disposed within the reactor body, such as a central electrode 406. In one example, the magnets are arranged so that the magnetic field is applied vertically, considering vertical uniformity variation is more tolerable. In any case, it may be advantageous to keep azimuthally uniform arrangement of the magnets.

FIG. 4B depicts a schematic cross-sectional view of the reactor body 400 having a gas distribution plate 410 disposed thereon according to embodiments of the disclosure. The gas distribution plate 410 is generally disposed between the reactor body 400 and a gas line 416 (such as the gas line 124, 216, 316 described above with respect to FIGS. 1-3). The gas distribution plate 410 may be a disc-shaped component stacked on top of the reactor body 400 as shown, or may be sized to fit within the reactor body 400. The gas distribution plate 410 may have a plurality holes 412 formed through the gas distribution plate 410 for a more uniform delivery of abatement reagents into the reactor body 400. The reactor body 400 is connected to a plasma gas delivery system (not shown, such as the plasma gas delivery system 110, 212, 312 described above with respect to FIGS. 1-3) through a delivery member 418 (such as the delivery member 126, 218, 318 described above with respect to FIGS. 1-3). The gas distribution plate 410 may be powered by the power source 408. If the delivery member is made of an electrical conductive material, an isolation ring 414 may be disposed between the reactor body 400 and the delivery member. The isolation ring 414 may be made from a ceramic and may have a high breakdown voltage to avoid sparking. In such a case, the power source 408 may be connected to the extrusions of the reactor body 400, with the delivery member connected to the ground.

FIG. 5A depicts a schematic top view of a reactor body 500 that may be used in place of the reactor body of FIGS. 1-3 according to embodiments of the present disclosure. The reactor body 500 may have a cylindrical shape defining a plasma excitation region therein. The reactor body 500 may be made of metal material, for example aluminum or stainless steel. Alternatively, the reactor body 500 may be made of coated metal, for example anodized aluminum or aluminum coated with nickel. Alternatively, the reactor body 500 may be made of refractory metal. Alternatively, the reactor body 500 may be made of insulating material, such as quartz or ceramic, or may be made of any other material that is suitable for performing a plasma process.

Similarly, the reactor body 500 may have a plurality of extrusions 502 extended inwardly from an interior surface of the reactor body 500 to a central electrode 506 disposed within the reactor body 500. The extrusions 502 may be machined out of a metal cylinder (i.e., the reactor body 500). Each of the extrusions 502 are electrically conductive and may serve as an electrode. The extrusions 502 can enhance gas ionization and boost plasma density, as discussed above with respect to extrusions 402. The extrusions 502 may be evenly spaced around the inner circumference 504 of the reactor body 500.

A power source 508, such as those power sources mentioned in FIGS. 1-3, may be connected to the central electrode 506 and/or the extrusions 502. In some embodiments, the reactor body 500 may be connected to the ground. The power source 508 may be a radio frequency (RF) power source and/or a direct current (DC) power source configured to provide a continuous RF power, a continuous DC power, a RF power having a RF pulsing frequency (e.g., 0.25-10 kHz), or a DC power having a DC pulsing frequency (e.g., 5-100 kHz).

FIG. 5B depicts a schematic cross-sectional view of the reactor body 500 having a gas distribution plate 510 disposed thereon according to embodiments of the disclosure. The gas distribution plate 510 is generally disposed between the reactor body 500 and a gas line 516 (such as the gas line 124, 216, 316 described above with respect to FIGS. 1-3). The gas distribution plate 510 may be a disc-shaped component stacked on top of the reactor body 500 as shown, or may be sized to fit within the reactor body 500. The gas distribution plate 510 may have a plurality holes formed through the gas distribution plate 510 for a more uniform delivery of abatement reagents into the reactor body 500. The reactor body 500 is connected to a plasma gas delivery system (not shown, such as the plasma gas delivery system 110, 212, 312 described above with respect to FIGS. 1-3) through a delivery member 518 (such as the delivery member 126, 218, 318 described above with respect to FIGS. 1-3). In one embodiment, the gas distribution plate 510 may be connected to the power source 508. In one embodiment, the gas distribution plate 510 and the delivery member may be both grounded. In such a case, the reactor body 500 may be electrically isolated from the gas distribution plate 510 and the delivery member by a first isolation ring 512 and a second isolation ring 514, respectively. The first and second isolation rings 512, 514 may be made from a ceramic and may have a high breakdown voltage to avoid sparking.

In summary, embodiments of the disclosure provide a remote plasma source dedicated for cleaning the exhaust pipe connected between a substrate processing chamber (having a substrate support disposed therein) and a pump. Benefits of the disclosure lie in that the remote plasma source provides only radicals and/or energetically excited neutral species of a cleaning or abatement gas into a downstream plasma gas delivery system, which is located in a flow path between the substrate processing chamber and the pump. These radicals and/or energetically excited neutral species of the cleaning gas react with post-process gases and/or other materials exiting the substrate processing chamber to convert them into a more environmentally and/or process equipment friendly composition before entering the pump. The reactive neutral species also react with that condensed films on pipeline wall, those long living ones can travel farther downstream and clean that deposited on moving components and inner surfaces of a pump. As a result, the condensation of deposition species within pipeline and the pump is avoided or minimized. Therefore, the pumping performance is improved. In addition, the upstream plasma source is implemented near the abatement site, rather than submerging the plasma source in the exhaust as implemented in the conventional system. In this manner, reactive species (neutrals) and some of the charged reactant are injected into the exhaust environment, and then react with the exhaust gas, which also clean the surface that includes the pump blades. Particularly, the upstream plasma reactor sees little deposition species and thus its electrical properties persist, thereby sustaining a long term plasma striking process. Furthermore, a magnetic field can be applied to confine the charged particle and keep them inside the reaction volume, in order to enhance plasma density inside the reactor.

While the foregoing is directed to embodiments of the present disclosure, other and further embodiments of the disclosure may be devised without departing from the basic scope thereof, and the scope thereof is determined by the claims that follow.

1. An apparatus, comprising:
a substrate processing chamber having a substrate support disposed therein;
a pump positioned to evacuate the substrate processing chamber; and
an abatement system, comprising:
a plasma gas delivery system positioned between the substrate processing chamber and the pump, the gas delivery system having a first end coupling to the substrate processing chamber and a second end coupling to the pump;
a reactor body connected to the plasma gas delivery system through a delivery member, the reactor body defining a plasma excitation region therein;
a cleaning gas source connected to the reactor body; and
a power source positioned to ionize within the plasma excitation region a cleaning gas from the cleaning gas source.

2. The apparatus of claim 1, wherein the reactor body is an inductively coupled plasma (ICP) chamber, a capacitively coupled plasma (CCP) chamber, a microwave induced (MW) plasma chamber, an electron cyclotron resonance (ECR) chamber, a high density plasma (HDP) chamber, an ultraviolet (UV) chamber, a filament of a hot wire chemical vapor deposition (HW-CVD) chamber, or any combination thereof.

3. The apparatus of claim 1, wherein the reactor body is a hybrid chamber including an inductively coupled plasma (ICP) configuration and a capacitively coupled plasma (CCP) configuration.

4. The apparatus of claim 1, wherein the power source provides an adjustable amount of RF power, DC power, microwave power, UV power, intense heat, electron synchrotron radiation, or any combination thereof.

5. The apparatus of claim 4, wherein the power source provides a continuous RF power, a continuous DC power, a RF power having a RF pulsing frequency, or a DC power having a DC pulsing frequency.

6. The apparatus of claim 1, wherein the plasma gas delivery system comprises a pipeline connecting to the substrate processing chamber, and the delivery member is positioned at an angle with respect to a longitudinal axis of the pipeline.

7. The apparatus of claim 6, wherein the angle is between about 20° and about 45° or between about 60° and about 110°.

8. The apparatus of claim 1, further comprising:
an ion filter disposed between the reactor body and the plasma gas delivery system to allow only radicals and/or energetically excited neutral species of the cleaning gas into the plasma gas delivery system through the delivery member.

9. The apparatus of claim 6, further comprising:
a first pressure regulating device disposed between the cleaning gas source and the reactor body to control the pressure inside the cleaning gas source to be relatively higher than the pressure inside the reactor body.

10. The apparatus of claim 9, further comprising:
a second pressure regulating device disposed between the substrate processing chamber and the plasma gas delivery system to control the pressure inside the pipeline to be relatively higher than the pressure inside the plasma gas delivery system.

11. The apparatus of claim 1, wherein the reactor body has a plurality of extrusions extended inwardly from an interior surface of the reactor body.

12. The apparatus of claim 11, wherein the extrusions are electrically conductive.

13. The apparatus of claim 11, wherein the extrusions are evenly spaced around an inner circumference of the reactor body.

14. The apparatus of claim 1, further comprising:
a gas distribution plate disposed between the reactor body and the cleaning gas source, wherein the gas distribution plate comprises a plurality holes formed through the gas distribution plate.

15. An apparatus, comprising:
a substrate processing chamber having a substrate support disposed therein;
a pump positioned to evacuate the substrate processing chamber; and
an abatement system, comprising:
a plasma gas delivery system positioned between the substrate processing chamber and the pump, the gas delivery system having a first end coupling to the substrate processing chamber and a second end coupling to the pump;
a reactor body connected to the plasma gas delivery system through a delivery member, the reactor body defining a plasma excitation region therein, wherein the delivery member is heated by a heating element;
a plurality of magnets disposed approximately around the reactor body to azimuthally provide a magnet field into the plasma excitation region of the reactor body;
a cleaning gas source connected to the reactor body; and
a power source positioned to ionize within the plasma excitation region a cleaning gas from the cleaning gas source.

16. An apparatus, comprising:
a substrate processing chamber having a substrate support disposed therein;
a vacuum pump disposed downstream of the substrate processing chamber to evacuate the substrate processing chamber; and
an abatement system positioned in a flow path between the substrate processing chamber and the vacuum pump, comprising:
a reactor body defining a plasma excitation region therein;
an abatement gas delivery system connected to a first end of the reactor body through a gas line;
a plasma gas delivery system connected to a second end of the reactor body through a delivery member, wherein a first end of the plasma gas delivery system is connected to the substrate processing chamber, and a second end of the plasma gas delivery system is connected to the pump; and
an ion filter disposed between the reactor body and the plasma gas delivery system to allow only radicals and/or energetically excited neutral species of the abatement reagent into the plasma gas delivery system through the delivery member.

17. The apparatus of claim 16, wherein the reactor body is an inductively coupled plasma (ICP) chamber, a capacitively coupled plasma (CCP) chamber, a microwave induced (MW) plasma chamber, an electron cyclotron resonance (ECR) chamber, a high density plasma (HDP) chamber, an ultraviolet (UV) chamber, a filament of a hot wire chemical vapor deposition (HW-CVD) chamber, or any combination thereof, and the power source provides an adjustable amount of RF power, DC power, microwave power, UV power, intense heat, electron synchrotron radiation, or any combination thereof.

18. The apparatus of claim 16, further comprising:
a first pressure regulating device disposed between the cleaning gas source and the reactor body to control the pressure inside the cleaning gas source to be relatively higher than the pressure inside the reactor body; and
a second pressure regulating device disposed between the substrate processing chamber and the plasma gas delivery system to control the pressure inside the substrate processing chamber is relatively higher than the pressure inside the plasma gas delivery system.

19. The apparatus of claim 16, wherein the reactor body has a plurality of electrically conductive extrusions extended inwardly from an interior surface of the reactor body.

20. The apparatus of claim 16, further comprising:
a gas distribution plate disposed between the reactor body and the cleaning gas source, wherein the gas distribution plate comprises a plurality holes formed through the gas distribution plate.
